(19) United States
(12) Patent Application Publication
(10) Pub. No.: US 2026/0305213 A1
(43) Pub. Date: Oct. 1, 2026

(54) METHOD FOR MANUFACTURING SEMICONDUCTOR DEVICE

(71) Applicant: Resonac Corporation, Tokyo (JP)

(72) Inventors: Kei ITAGAKI, Tokyo (JP); Huy Hoang HUYNH, Tokyo (JP); Kanami NAKAMURA, Tokyo (JP)

(21) Appl. No.: 19/479,495

(22) PCT Filed: Oct. 10, 2024
(86) PCT No.: PCT/JP2024/036359

§ 371 Date: Oct. 28, 2025

(30) Foreign Application Priority Data
Oct. 11, 2023 (JP) 2023-176155

(51) Int. Cl. H10P 58/00; H10P 34/42

(52) U.S. Cl. CPC H10P 58/00; H10P 34/42

(57) ABSTRACT

A method for manufacturing a semiconductor device is disclosed. The method for manufacturing a semiconductor device includes providing a laminate including a dicing/die-bonding integrated film having, in this order, a base layer, a pressure-sensitive adhesive layer, and an adhesive layer, and a plurality of semiconductor chips obtained by singulating a semiconductor wafer, the plurality of semiconductor chips being disposed on the adhesive layer of the dicing/die-bonding integrated film; irradiating the adhesive layer with a laser through gaps between the plurality of semiconductor chips to form a groove in the adhesive layer; and singulating the adhesive layer in which the groove has been formed by expanding the base layer to produce semiconductor chips with adhesive layer pieces attached. A thickness of the adhesive layer is from 30 to 50 μm, and a depth of the groove is 45% or less of the thickness of the adhesive layer.

### TECHNICAL FIELD

The present disclosure relates to a method for manufacturing a semiconductor device.

### BACKGROUND ART

In recent years, with the trend toward smaller/thinner, higher-capacity/more-functional semiconductor packages, semiconductor chips are also being made thinner. In the thinning of semiconductor chips, problems during processing, such as damage to the semiconductor wafer, tend to occur more easily. Therefore, the manufacturing process for semiconductor devices is also changing from conventional ones. As a process to suppress problems in thinning semiconductor chips, for example, a dicing before grinding (DBG) process is known. The DBG process, unlike the conventional process in which a dicing step is performed after a back grinding step, is a process in which a back grinding step is performed after a dicing step. More specifically, it is a process in which a groove is formed by half-cut dicing along a dicing line on a circuit-forming surface of a semiconductor wafer, and subsequently, a back surface of the semiconductor wafer, which is opposite to the circuit-forming surface, is ground (back-ground) to a depth that at least reaches the groove, thereby simultaneously thinning and singulating the semiconductor wafer (see, for example, Patent Literatures 1 and 2). According to such a process, it becomes possible to produce thinned semiconductor chips while suppressing problems during processing.

In the DBG process, a film called a dicing/die-bonding integrated film is attached to the back surface side of the semiconductor chip. The dicing/die-bonding integrated film has a structure in which a base layer, a pressure-sensitive adhesive layer, and an adhesive layer are laminated in this order, and the adhesive layer is attached to the back surface side of the semiconductor chip. Thereafter, by singulating the adhesive layer, a semiconductor chip with an adhesive layer piece attached, which is composed of the semiconductor chip and the singulated adhesive layer, can be obtained. In the singulation of the adhesive layer, a method of separating the adhesive layer using a laser is known (see, for example, Patent Literatures 3 and 4).

### CITATION LIST

### Patent Literature

Patent Literature 1: WO 2016/189986 A1
Patent Literature 2: JP 2011-181951 A1
Patent Literature 3: JP 2018-190940 A1
Patent Literature 4: JP 2019-121646 A1

### SUMMARY OF INVENTION

### Technical Problem

In the singulation of the adhesive layer, a method is also known in which a groove is formed in the adhesive layer using a laser, and then the adhesive layer is separated by expanding the base layer of the dicing/die-bonding integrated film under cooling conditions. The present inventors have studied this method and found that laser irradiation of the adhesive layer tends to cause debris derived from the adhesive layer to adhere to the surface, side surfaces, etc., of the semiconductor chip. If a large amount of debris derived from the adhesive layer adheres to the semiconductor chip, a process to remove them becomes necessary, which may reduce the manufacturing yield of the semiconductor chip.

An object of the present disclosure is to provide a method for manufacturing a semiconductor device that can suppress the adhesion of debris derived from the adhesive layer on semiconductor chips.

### Solution to Problem

As a result of diligent studies to solve the above problem, the present inventors have found that laser irradiation of the adhesive layer causes a resin component climb-up of the adhesive layer on the side surfaces of the semiconductor chip. FIG. 4 is an SEM (scanning electron microscope) image of a side surface of a semiconductor chip taken after forming a groove in the adhesive layer and expanding it under cooling conditions, where FIG. 4(a) is an SEM image of Example 1, and FIG. 4(b) is an SEM image of Comparative Example 1. In FIG. 4, thickness A represents the thickness of the adhesive layer after laser irradiation and expansion under cooling conditions, and thickness B represents the thickness of the separated portion of the adhesive layer separated by expansion. The resin component climb-up of the adhesive layer means a phenomenon in which the thickness of the adhesive layer becomes greater after laser irradiation than before laser irradiation. It is presumed that the resin component that has climbed up is easily scattered, and this becomes a cause of debris generation. According to further studies by the present inventors, it has been found that there is a correlation between the climb-up height (climb-up amount) of the resin component of the adhesive layer and the depth of the groove in the adhesive layer formed by the laser. That is, it is presumed that as the depth of the groove in the adhesive layer formed by the laser increases, the climb-up height (climb-up amount) of the resin component of the adhesive layer also increases, and thus the scattering of debris becomes more widespread. On the other hand, it was predicted that if the depth of the groove in the adhesive layer formed by the laser is small, a sufficient kerf width (gap between semiconductor chips) between the semiconductor chips cannot be obtained after expansion. However, the present inventors have unexpectedly found that a sufficient kerf width between the semiconductor chips can be obtained even in such a case, and have completed the invention of the present disclosure.

The present disclosure provides the methods for manufacturing a semiconductor device described in [1] and [2].

[1] A method for manufacturing a semiconductor device, the method including:
providing a laminate including a dicing/die-bonding integrated film having, in this order, a base layer, a pressure-sensitive adhesive layer, and an adhesive layer, and a plurality of semiconductor chips obtained by singulating a semiconductor wafer, the plurality of semiconductor chips being disposed on the adhesive layer of the dicing/die-bonding integrated film;
irradiating the adhesive layer with a laser through gaps between the plurality of semiconductor chips to form a groove in the adhesive layer; and
singulating the adhesive layer in which the groove has been formed by expanding the base layer to produce semiconductor chips with adhesive layer pieces attached,
wherein a thickness of the adhesive layer is from 30 to 50 μm, and
a depth of the groove is 45% or less of the thickness of the adhesive layer.

[2] The method according to [1],
wherein the laminate is a laminate produced by a method including:
forming a groove along a dicing line on a circuit-forming surface of the semiconductor wafer;
grinding a back surface, which is opposite to the circuit-forming surface, of the semiconductor wafer in which the groove has been formed to at least a depth reaching the groove to produce the plurality of semiconductor chips; and
attaching the adhesive layer of the dicing/die-bonding integrated film to back surfaces of the plurality of semiconductor chips.

### Advantageous Effects of Invention

According to the present disclosure, a method for manufacturing a semiconductor device that can suppress the adhesion of debris derived from the adhesive layer on semiconductor chips is provided. Some embodiments of the method for manufacturing a semiconductor device are also excellent in that a sufficient kerf width between the semiconductor chips can be obtained after expansion.

### BRIEF DESCRIPTION OF DRAWINGS

FIG. 1 is a schematic cross-sectional view for explaining one embodiment of a method for manufacturing a semiconductor device, and FIGS. 1(a), 1(b), 1(c), and 1(d) are diagrams showing each step.

FIG. 2 is a schematic cross-sectional view for explaining one embodiment of a method for manufacturing a semiconductor device, and FIGS. 2(a), 2(b), 2(c), and 2(d) are diagrams showing each step.

FIG. 3 is a schematic cross-sectional view for explaining one embodiment of a method for manufacturing a laminate, and FIGS. 3(a), 3(b), 3(c), 3(d), 3(e), and 3(f) are diagrams showing each step.

FIG. 4 is an SEM (scanning electron microscope) image of a side surface of a semiconductor chip taken after forming a groove in the adhesive layer and expanding it under cooling conditions, where FIG. 4(a) is an SEM image of Example 1, and FIG. 4(b) is an SEM image of Comparative Example 1.

### DESCRIPTION OF EMBODIMENTS

Hereinafter, embodiments will be described in detail with reference to the drawings. However, the present disclosure is not limited to the following embodiments. In the following embodiments, the constituent elements (including steps, etc.) are not essential unless otherwise specified. The same or corresponding parts are denoted by the same reference signs, and redundant descriptions are omitted. In addition, positional relationships such as up, down, left, and right are based on the positional relationships shown in the drawings, unless otherwise specified. The size of the constituent elements in each drawing is conceptual, and the relative relationship of the sizes between the constituent elements is not limited to that shown in each drawing.

The same applies to the numerical values and their ranges in the present disclosure, and they do not limit the present disclosure. In this specification, a numerical range indicated using “~” indicates a range including the numerical values described before and after “~” as the minimum and maximum values, respectively. In the numerical ranges described stepwise in this specification, the upper limit value or lower limit value described in one numerical range may be replaced with the upper limit value or lower limit value of another stepwise described numerical range. Furthermore, in the numerical ranges described in this specification, the upper limit value or lower limit value of the numerical range may be replaced with the value shown in the Examples. In addition, individually described upper and lower limit values can be arbitrarily combined.

In this specification, the term “layer” includes not only a structure having a shape formed over the entire surface when observed as a plan view, but also a structure having a shape formed in a part thereof. In this specification, the term “step” or “process” is not limited to an independent step, but is included in this term as long as the intended action of the step is achieved, even if it cannot be clearly distinguished from other steps.

In this specification, “(meth)acrylate” means at least one of acrylate and the corresponding methacrylate. The same applies to other similar expressions such as “(meth)acryloyl” and “(meth)acrylic acid”.

“A or B” means that it may contain either A or B, and may contain both. In addition, the materials exemplified below may be used alone or in combination of two or more, unless otherwise specified. The content of each component in a composition means the total amount of the plurality of substances corresponding to each component present in the composition, unless otherwise specified.

### [Method for Manufacturing Semiconductor Device]

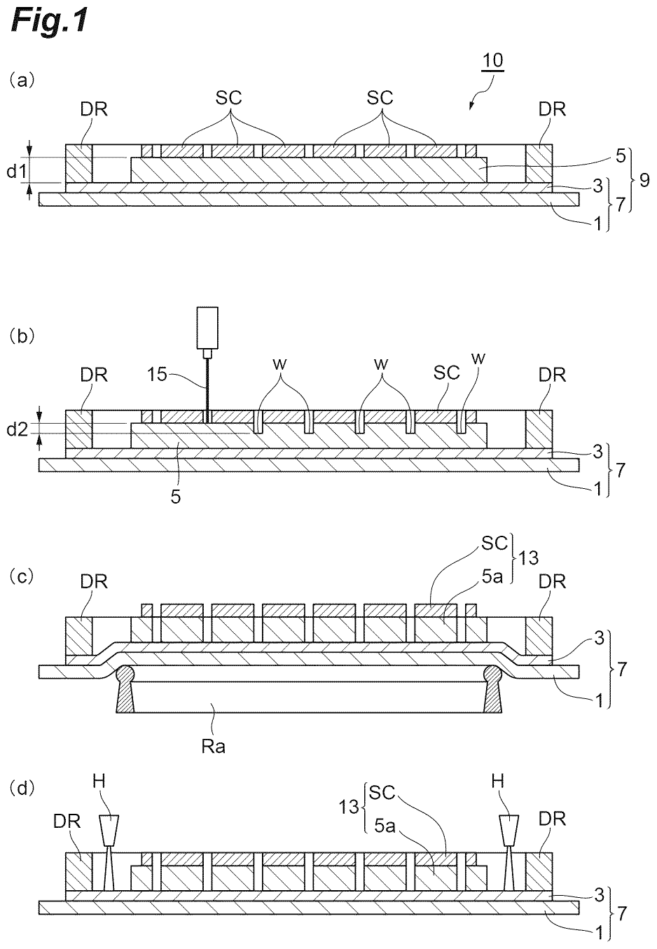

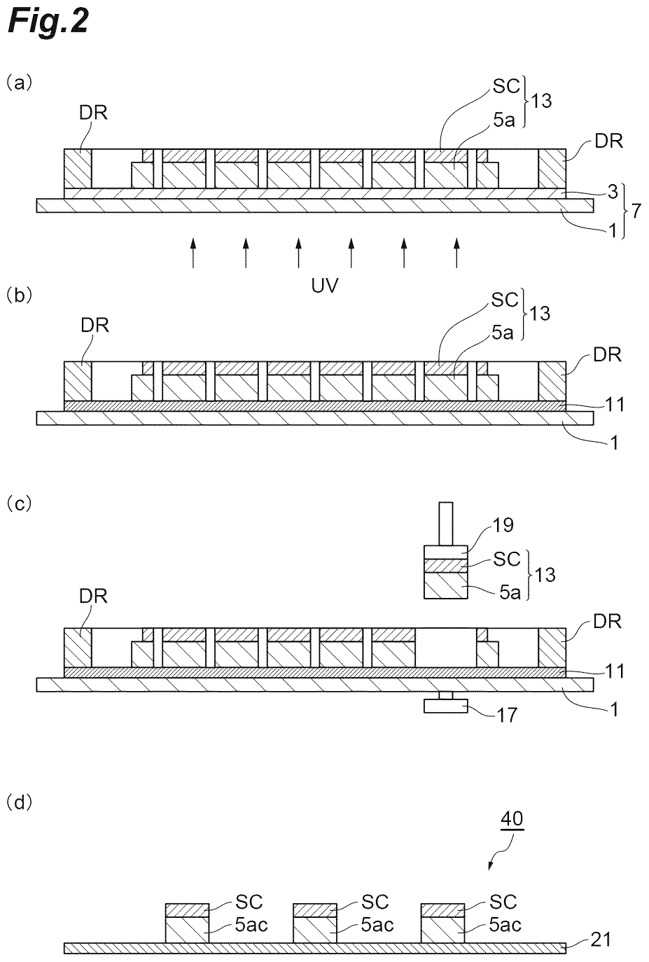

A method for manufacturing a semiconductor device according to one embodiment includes providing a laminate (step (A)) including a dicing/die-bonding integrated film (hereinafter, sometimes referred to as an “integrated film”) having, in this order, a base layer, a pressure-sensitive adhesive layer, and an adhesive layer, and a plurality of semiconductor chips obtained by singulating a semiconductor wafer, the plurality of semiconductor chips being disposed on the adhesive layer of the integrated film; irradiating the adhesive layer with a laser through gaps between the plurality of semiconductor chips to form a groove in the adhesive layer (step (B)); and singulating the adhesive layer in which the groove has been formed by expanding the base layer to produce semiconductor chips with adhesive layer pieces attached (step (C)). FIGS. 1 and 2 are schematic cross-sectional views for explaining one embodiment of the method for manufacturing a semiconductor device.

### <Step (A)>

In this step, a laminate 10 is provided, which includes an integrated film 9 having a base layer 1, a pressure-sensitive adhesive layer 3, and an adhesive layer 5 in this order, and a plurality of semiconductor chips SC obtained by singulating a semiconductor wafer, the plurality of semiconductor chips SC being disposed on the adhesive layer 5 of the integrated film 9 (see FIG. 1(a)). In the laminate 10, a dicing ring DR for fixing the semiconductor chips SC may be attached on the surface of the pressure-sensitive adhesive layer 3 opposite to the base layer 1. A laminated film having a base layer and a pressure-sensitive adhesive layer provided on the base layer is referred to as a dicing film.

### (Base Layer)

For the base layer 1, a known polymer sheet or film can be used. Specific examples of the base layer 1 include polyolefins such as crystalline polypropylene, amorphous polypropylene, high-density polyethylene, medium-density polyethylene, low-density polyethylene, ultra-low-density polyethylene, linear low-density polyethylene, polybutene, and polymethylpentene; ethylene-vinyl acetate copolymer; ionomer resin; ethylene-(meth)acrylic acid copolymer; ethylene-(meth)acrylic acid ester (random, alternating) copolymer; ethylene-butene copolymer; ethylene-hexene copolymer; polyurethane; polyesters such as polyethylene terephthalate and polyethylene naphthalate; polycarbonate; polyimide; polyetheretherketone; polyetherimide; polyamide; wholly aromatic polyamide; polyphenylene sulfide; aramid (paper); glass; glass cloth; fluororesin; polyvinyl chloride; polyvinylidene chloride; cellulosic resin; silicone resin; or a mixture of these with a plasticizer, or a cured product obtained by crosslinking through electron beam irradiation.

The base layer 1 may have a surface whose main component is at least one resin selected from the group consisting of polyethylene, polypropylene, polyethylene-polypropylene random copolymer, and polyethylene-polypropylene block copolymer, and this surface may be in contact with the pressure-sensitive adhesive layer 3. These resins can be a good base material also from the viewpoints of properties such as Young's modulus, stress relaxation properties, and melting point, as well as cost and recycling of waste material after use. The base layer 1 may be a single layer, or may have a multilayer structure in which layers made of different materials are laminated, as necessary. From the viewpoint of controlling adhesion with the pressure-sensitive adhesive layer 3, the base layer 1 may be subjected to a surface roughening treatment such as a mat treatment or a corona treatment on its surface.

The thickness of the base layer 1 may be, for example, from 10 to 200 μm or from 20 to 170 μm.

### (Pressure-Sensitive Adhesive Layer)

The pressure-sensitive adhesive layer 3 may, for example, include an ultraviolet-curable pressure-sensitive adhesive or a non-ultraviolet-curable pressure-sensitive adhesive, and may include an ultraviolet-curable pressure-sensitive adhesive. The ultraviolet-curable pressure-sensitive adhesive may, in one embodiment, include a (meth)acrylic resin having a chain-polymerizable functional group (hereinafter, sometimes referred to as “(meth)acrylic resin (A)”) and a photoinitiator. At least a part of the (meth)acrylic resin (A) may be crosslinked by a crosslinking agent. The pressure-sensitive adhesive layer 3 may, in one embodiment, be made of an ultraviolet-curable pressure-sensitive adhesive. The pressure-sensitive adhesive layer 3 may, in one embodiment, be made of a non-ultraviolet-curable pressure-sensitive adhesive.

The (meth)acrylic resin (A) has a chain-polymerizable functional group (hereinafter, sometimes referred to as “functional group (A)”). The functional group (A) may be at least one selected from an acryloyl group and a methacryloyl group.

The content of the functional group (A) in the (meth)acrylic resin (A) may be, for example, from 0.1 to 1.2 mmol/g, and may be from 0.3 to 1.0 mmol/g or from 0.5 to 0.8 mmol/g.

The (meth)acrylic resin (A) can be obtained by reacting a (meth)acrylic resin (hereinafter, sometimes referred to as “(meth)acrylic resin (B)”) having at least one functional group selected from a hydroxyl group, a glycidyl group (epoxy group), an amino group, and the like (hereinafter, sometimes referred to as “functional group (B)”), with a compound for introducing the after-mentioned functional group (A) (hereinafter, sometimes referred to as “compound for introducing functional group (A)”). The (meth)acrylic resin (A) can also be referred to as a reaction product of the (meth)acrylic resin (B) and the compound for introducing functional group (A).

The (meth)acrylic resin (B) can be obtained by synthesis using a known method. Examples of the synthesis method include solution polymerization, suspension polymerization, emulsion polymerization, bulk polymerization, precipitation polymerization, gas-phase polymerization, plasma polymerization, and supercritical polymerization. In addition, as for the type of polymerization reaction, examples include radical polymerization, cationic polymerization, anionic polymerization, living radical polymerization, living cationic polymerization, living anionic polymerization, coordination polymerization, immortal polymerization, and the like, as well as techniques such as ATRP (atom transfer radical polymerization) and RAFT (reversible addition-fragmentation chain transfer polymerization). Among these, synthesis by radical polymerization using a solution polymerization method has advantages such as good economy, high reaction rate, ease of polymerization control, and the ability to use the resin solution obtained by polymerization as it is for formulation.

Here, the synthesis method of the (meth)acrylic resin (B) will be described in detail, taking as an example a method of obtaining the (meth)acrylic resin (B) by radical polymerization using a solution polymerization method.

The monomer used for synthesizing the (meth)acrylic resin (B) is not particularly limited as long as it has one (meth)acryloyl group in one molecule. Specific examples thereof include aliphatic (meth)acrylates such as methyl (meth)acrylate, ethyl (meth)acrylate, butyl (meth)acrylate, isobutyl (meth)acrylate, tert-butyl (meth)acrylate, butoxyethyl (meth)acrylate, isoamyl (meth)acrylate, hexyl (meth)acrylate, 2-ethylhexyl (meth)acrylate, heptyl (meth)acrylate, octylheptyl (meth)acrylate, nonyl (meth)acrylate, decyl (meth)acrylate, undecyl (meth)acrylate, lauryl (meth)acrylate, tridecyl (meth)acrylate, tetradecyl (meth)acrylate, pentadecyl (meth)acrylate, hexadecyl (meth)acrylate, stearyl (meth)acrylate, behenyl (meth)acrylate, methoxypolyethylene glycol (meth)acrylate, ethoxypolyethylene glycol (meth)acrylate, methoxypolypropylene glycol (meth)acrylate, ethoxypolypropylene glycol (meth)acrylate, and mono(2-(meth)acryloyloxyethyl) succinate; alicyclic (meth)acrylates such as cyclopentyl (meth)acrylate, cyclohexyl (meth)acrylate, dicyclopentanyl (meth)acrylate, dicyclopentenyl (meth)acrylate, isobornyl (meth)acrylate, mono(2-(meth)acryloyloxyethyl)tetrahydrophthalate, and mono(2-(meth)acryloyloxyethyl) hexahydrophthalate; aromatic (meth)acrylates such as benzyl (meth)acrylate, phenyl (meth)acrylate, o-biphenyl (meth)acrylate, 1-naphthyl (meth)acrylate, 2-naphthyl (meth)acrylate, phenoxyethyl (meth)acrylate, p-cumylphenoxyethyl (meth)acrylate, o-phenylphenoxyethyl (meth)acrylate, 1-naphthoxyethyl (meth)acrylate, 2-naphthoxyethyl (meth)acrylate, phenoxypolyethylene glycol (meth)acrylate, nonylphenoxypolyethylene glycol (meth)acrylate, phenoxypolypropylene glycol (meth)acrylate, 2-hydroxy-3-phenoxypropyl (meth)acrylate, 2-hydroxy-3-(o-phenylphenoxy) propyl (meth)acrylate, 2-hydroxy-3-(1-naphthoxy) propyl (meth)acrylate, and 2-hydroxy-3-(2-naphthoxy) propyl (meth)acrylate; heterocyclic (meth)acrylates such as 2-tetrahydrofurfuryl (meth)acrylate, N-(meth)acryloyloxyethylhexahydrophthalimide, and 2-(meth)acryloyloxyethyl-N-carbazole, caprolactone-modified products thereof, ω-carboxy-polycaprolactone mono(meth)acrylate, glycidyl (meth)acrylate, α-ethylglycidyl (meth)acrylate, α-propylglycidyl (meth)acrylate, α-butylglycidyl (meth)acrylate, 2-methylglycidyl (meth)acrylate, 2-ethylglycidyl (meth)acrylate, 2-propylglycidyl (meth)acrylate, 3,4-epoxybutyl (meth)acrylate, 3,4-epoxyheptyl (meth)acrylate, α-ethyl-6,7-epoxyheptyl (meth)acrylate, 3,4-epoxycyclohexylmethyl (meth)acrylate, compounds having an ethylenically unsaturated group and an epoxy group such as o-vinylbenzyl glycidyl ether, m-vinylbenzyl glycidyl ether, and p-vinylbenzyl glycidyl ether; compounds having an ethylenically unsaturated group and an oxetanyl group such as (2-ethyl-2-oxetanyl) methyl (meth)acrylate, (2-methyl-2-oxetanyl) methyl (meth)acrylate, 2-(2-ethyl-2-oxetanyl)ethyl (meth)acrylate, 2-(2-methyl-2-oxetanyl)ethyl (meth)acrylate, 3-(2-ethyl-2-oxetanyl) propyl (meth)acrylate, and 3-(2-methyl-2-oxetanyl) propyl (meth)acrylate; compounds having an ethylenically unsaturated group and an isocyanate group such as 2-(meth)acryloxyethyl isocyanate; and compounds having an ethylenically unsaturated group and a hydroxyl group such as 2-hydroxyethyl (meth)acrylate, 2-hydroxypropyl (meth)acrylate, 4-hydroxybutyl (meth)acrylate, 3-chloro-2-hydroxypropyl (meth)acrylate, and 2-hydroxybutyl (meth)acrylate. The target (meth)acrylic resin (B) can be synthesized by appropriately combining these.

The (meth)acrylic resin (B) has at least one functional group (B) selected from a hydroxyl group, a glycidyl group (epoxy group), an amino group, and the like, as a reaction point with a compound for introducing the functional group (A) described later or a crosslinking agent.

Examples of the monomer for synthesizing the (meth)acrylic resin (B) having a hydroxyl group include compounds having an ethylenically unsaturated group and a hydroxyl group, such as 2-hydroxyethyl (meth)acrylate, 2-hydroxypropyl (meth)acrylate, 4-hydroxybutyl (meth)acrylate, 3-chloro-2-hydroxypropyl (meth)acrylate, and 2-hydroxybutyl (meth)acrylate.

Examples of the monomer for synthesizing the (meth)acrylic resin (B) having a glycidyl group include compounds having an ethylenically unsaturated group and an epoxy group, such as glycidyl (meth)acrylate, α-ethylglycidyl (meth)acrylate, α-propylglycidyl (meth)acrylate, α-butylglycidyl (meth)acrylate, 2-methylglycidyl (meth)acrylate, 2-ethylglycidyl (meth)acrylate, 2-propylglycidyl (meth)acrylate, 3,4-epoxybutyl (meth)acrylate, 3,4-epoxyheptyl (meth)acrylate, α-ethyl-6,7-epoxyheptyl (meth)acrylate, 3,4-epoxycyclohexylmethyl (meth)acrylate, o-vinylbenzyl glycidyl ether, m-vinylbenzyl glycidyl ether, and p-vinylbenzyl glycidyl ether.

The (meth)acrylic resin (A) has a functional group (A) such as an acryloyl group or a methacryloyl group. The functional group (A) can be introduced into the (meth)acrylic resin (B), for example, by reacting a compound for introducing the functional group (A) with the (meth)acrylic resin (B) having at least one functional group (B) selected from a hydroxyl group, a glycidyl group (epoxy group), an amino group, and the like. Specific examples of the compound for introducing the functional group (A) include 2-methacryloyloxyethyl isocyanate, α,α-dimethyl-4-isopropenylbenzyl isocyanate, allyl isocyanate, 1,1-(bisacryloxymethyl)ethyl isocyanate; acryloyl monoisocyanate compounds obtained by the reaction of a diisocyanate compound or a polyisocyanate compound with hydroxyethyl (meth)acrylate or 4-hydroxybutylethyl (meth)acrylate; and acryloyl monoisocyanate compounds obtained by the reaction of a diisocyanate compound or a polyisocyanate compound with a polyol compound and hydroxyethyl (meth)acrylate. Among these, the compound for introducing the functional group (A) may be 2-methacryloyloxyethyl isocyanate.

In the (meth)acrylic resin (A), a part of the reaction points, which are at least one functional group (B) mainly derived from the (meth)acrylic resin (B) and selected from a hydroxyl group, a glycidyl group (epoxy group), an amino group, and the like, may be crosslinked by a crosslinking agent. That is, at least a part of the (meth)acrylic resin (A) may be crosslinked by a crosslinking agent. The ultraviolet-curable pressure-sensitive adhesive may include the (meth)acrylic resin (A), which may be crosslinked by a crosslinking agent.

The crosslinking agent is used, for example, for the purpose of controlling the storage modulus and/or tackiness of the pressure-sensitive adhesive layer. The crosslinking agent may be any compound having two or more functional groups (hereinafter, sometimes referred to as “functional group (C)”) in one molecule that can react with at least one functional group (B) derived from the (meth)acrylic resin (B) that can remain in the (meth)acrylic resin (A), the functional group (B) being selected from a hydroxyl group, a glycidyl group (epoxy group), an amino group, and the like. Examples of the bond formed by the reaction between the (meth)acrylic resin (A) and the crosslinking agent include an ester bond, an ether bond, an amide bond, an imide bond, a urethane bond, a urea bond, and the like.

The functional group (C) in the crosslinking agent may be an isocyanate group. That is, the crosslinking agent may be, for example, a polyfunctional isocyanate having two or more isocyanate groups in one molecule. When such a polyfunctional isocyanate is used, it easily reacts with the functional group (B) derived from the (meth)acrylic resin (B) that can remain in the (meth)acrylic resin (A), and a strong crosslinked structure can be formed.

Examples of the polyfunctional isocyanate having two or more isocyanate groups in one molecule include isocyanate compounds such as 2,4-tolylene diisocyanate, 2,6-tolylene diisocyanate, 1,3-xylylene diisocyanate, 1,4-xylene diisocyanate, diphenylmethane-4,4′-diisocyanate, diphenylmethane-2,4′-diisocyanate, 3-methyldiphenylmethane diisocyanate, hexamethylene diisocyanate, isophorone diisocyanate, dicyclohexylmethane-4,4′-diisocyanate, dicyclohexylmethane-2,4′-diisocyanate, and lysine isocyanate.

The crosslinking agent may be a reaction product (isocyanate group-containing oligomer) of a polyfunctional isocyanate and a polyhydric alcohol having two or more hydroxy groups in one molecule. Examples of the polyhydric alcohol having two or more hydroxy groups in one molecule include ethylene glycol, propylene glycol, butylene glycol, 1,6-hexanediol, 1,8-octanediol, 1,9-nonanediol, 1,10-decanediol, 1,11-undecanediol, 1,12-dodecanediol, glycerin, trimethylolpropane, pentaerythritol, dipentaerythritol, 1,4-cyclohexanediol, 1,3-cyclohexanediol, and the like.

Among these, the crosslinking agent may be a reaction product (isocyanate group-containing oligomer) of a polyfunctional isocyanate having two or more isocyanate groups in one molecule and a polyhydric alcohol having three or more hydroxy groups in one molecule. By using such an isocyanate group-containing oligomer as the crosslinking agent, the pressure-sensitive adhesive layer 3 forms a dense crosslinked structure, and as a result, there is a tendency that adhesion of the pressure-sensitive adhesive to the adhesive layer 5 in the pick-up step can be suppressed.

The content of the crosslinking agent when reacting the (meth)acrylic resin (A) with the crosslinking agent can be appropriately set according to the cohesive force, elongation at break, adhesion to the adhesive layer, and the like required for the pressure-sensitive adhesive layer 3. The content of the crosslinking agent may be, for example, from 0.1 to 10 parts by mass, from 0.2 to 7 parts by mass, or from 0.3 to 5 parts by mass, with respect to 100 parts by mass of the total amount of the (meth)acrylic resin (A).

The (meth)acrylic resin (A) can be the main component of the ultraviolet-curable pressure-sensitive adhesive (or the pressure-sensitive adhesive layer 3). The content of the (meth)acrylic resin (A) may be 80% by mass or more, 85% by mass or more, 90% by mass or more, 95% by mass or more, or 98% by mass or more, based on the total amount of the ultraviolet-curable pressure-sensitive adhesive (or the pressure-sensitive adhesive layer 3).

The photoinitiator is not particularly limited as long as it generates a chain-polymerizable active species upon irradiation with ultraviolet light. Examples of the photoinitiator include a photoradical polymerization initiator and the like. Here, the chain-polymerizable active species means a species that initiates a polymerization reaction by reacting with a chain-polymerizable functional group.

Examples of the photoradical polymerization initiator include benzoin ketals such as 2,2-dimethoxy-1,2-diphenylethan-1-one; α-hydroxyketones such as 1-hydroxycyclohexyl phenyl ketone, 2-hydroxy-2-methyl-1-phenylpropan-1-one, and 1-[4-(2-hydroxyethoxy)phenyl]-2-hydroxy-2-methyl-1-propan-1-one; α-aminoketones such as 2-benzyl-2-dimethylamino-1-(4-morpholinophenyl)-butan-1-one and 1,2-methyl-1-[4-(methylthio)phenyl]-2-morpholinopropan-1-one; oxime esters such as 1-[4-(phenylthio)phenyl]-1,2-octanedione-2-(benzoyl) oxime; phosphine oxides such as bis(2,4,6-trimethylbenzoyl)phenylphosphine oxide, bis(2,6-dimethoxybenzoyl)-2,4,4-trimethylpentylphosphine oxide, and 2,4,6-trimethylbenzoyldiphenylphosphine oxide; 2,4,5-triarylimidazole dimers such as 2-(o-chlorophenyl)-4,5-diphenylimidazole dimer, 2-(o-chlorophenyl)-4,5-di(methoxyphenyl) imidazole dimer, 2-(O-fluorophenyl)-4,5-diphenylimidazole dimer, 2-(o-methoxyphenyl)-4,5-diphenylimidazole dimer, and 2-(p-methoxyphenyl)-4,5-diphenylimidazole dimer; benzophenone compounds such as benzophenone, N,N,N′,N′-tetramethyl-4,4′-diaminobenzophenone, N,N,N′,N′-tetraethyl-4,4′-diaminobenzophenone, and 4-methoxy-4′-dimethylaminobenzophenone; quinone compounds such as 2-ethylanthraquinone, phenanthrenequinone, 2-tert-butylanthraquinone, octamethylanthraquinone, 1,2-benzanthraquinone, 2,3-benzanthraquinone, 2-phenylanthraquinone, 2,3-diphenylanthraquinone, 1-chloroanthraquinone, 2-methylanthraquinone, 1,4-naphthoquinone, 9,10-phenanthraquinone, 2-methyl-1,4-naphthoquinone, and 2,3-dimethylanthraquinone; benzoin ethers such as benzoin methyl ether, benzoin ethyl ether, and benzoin phenyl ether; benzoin compounds such as benzoin, methylbenzoin, and ethylbenzoin; benzyl compounds such as benzyl dimethyl ketal; acridine compounds such as 9-phenylacridine and 1,7-bis(9,9′-acridinylheptane); N-phenylglycine, coumarin, and the like.

The content of the photoinitiator in the ultraviolet-curable pressure-sensitive adhesive may be, for example, from 0.1 to 30 parts by mass, from 0.3 to 10 parts by mass, or from 0.5 to 5 parts by mass, with respect to 100 parts by mass of the total amount of the (meth)acrylic resin (A).

The pressure-sensitive adhesive layer 3 may include other components. Examples of other components include resins other than the (meth)acrylic resin having a chain-polymerizable functional group (such as acrylic monomers or oligomers, urethane monomers or oligomers), tackifiers (such as tackifier resins), antistatic agents, fillers (such as organic fillers, inorganic fillers), and the like.

The thickness of the pressure-sensitive adhesive layer 3 may be, for example, 1 μm or more, 2 μm or more, 3 μm or more, or 5 μm or more, and may be 100 μm or less, 50 μm or less, 20 μm or less, or 15 μm or less.

In the dicing film 7, the pressure-sensitive adhesive layer 3 is formed on the base layer 1. As a method for forming the pressure-sensitive adhesive layer 3, a known technique can be adopted. For example, a laminate of the base layer 1 and the pressure-sensitive adhesive layer 3 may be formed by a two-layer extrusion method, or a varnish of the ultraviolet-curable pressure-sensitive adhesive (varnish for forming the pressure-sensitive adhesive layer) may be prepared and coated on the surface of the base layer 1, or the pressure-sensitive adhesive layer 3 may be formed on a release-treated film and then transferred to the base layer 1.

The varnish of the ultraviolet-curable pressure-sensitive adhesive (varnish for forming the pressure-sensitive adhesive layer) may be an organic solvent that can dissolve the ultraviolet-curable pressure-sensitive adhesive ((meth)acrylic resin (A), photoinitiator, crosslinking agent, etc.) and volatilizes upon heating. Specific examples of the organic solvent include aromatic hydrocarbons such as toluene, xylene, mesitylene, cumene, and p-cymene; cyclic ethers such as tetrahydrofuran and 1,4-dioxane; alcohols such as methanol, ethanol, isopropanol, butanol, ethylene glycol, and propylene glycol; ketones such as acetone, methyl ethyl ketone, methyl isobutyl ketone, cyclohexanone, and 4-hydroxy-4-methyl-2-pentanone; esters such as methyl acetate, ethyl acetate, butyl acetate, methyl lactate, ethyl lactate, and γ-butyrolactone; carbonate esters such as ethylene carbonate and propylene carbonate; polyhydric alcohol alkyl ethers such as ethylene glycol monomethyl ether, ethylene glycol monoethyl ether, ethylene glycol monobutyl ether, ethylene glycol dimethyl ether, ethylene glycol diethyl ether, propylene glycol monomethyl ether, propylene glycol monoethyl ether, propylene glycol dimethyl ether, propylene glycol diethyl ether, diethylene glycol monomethyl ether, diethylene glycol monoethyl ether, diethylene glycol monobutyl ether, diethylene glycol dimethyl ether, and diethylene glycol diethyl ether; polyhydric alcohol alkyl ether acetates such as ethylene glycol monomethyl ether acetate, ethylene glycol monoethyl ether acetate, ethylene glycol monobutyl ether acetate, propylene glycol monomethyl ether acetate, propylene glycol monoethyl ether acetate, diethylene glycol monomethyl ether acetate, and diethylene glycol monoethyl ether acetate; and amides such as N,N-dimethylformamide, N,N-dimethylacetamide, and N-methyl-2-pyrrolidone.

Among these, the organic solvent may be at least one selected from the group consisting of toluene, methanol, ethanol, isopropanol, acetone, methyl ethyl ketone, methyl isobutyl ketone, cyclohexanone, methyl acetate, ethyl acetate, butyl acetate, ethylene glycol monomethyl ether, ethylene glycol monoethyl ether, propylene glycol monomethyl ether, propylene glycol monoethyl ether, diethylene glycol dimethyl ether, ethylene glycol monomethyl ether acetate, propylene glycol monomethyl ether acetate, and N,N-dimethylacetamide, from the viewpoints of solubility and boiling point. The solid content concentration of the varnish is usually from 10 to 60% by mass.

### (Adhesive Layer)

The adhesive layer 5 can be formed using a known die bonding film (a film used for adhesion between a semiconductor chip and a support member or for adhesion between semiconductor chips) or an adhesive composition constituting it. The adhesive composition constituting the adhesive layer 5 may, for example, include an epoxy resin, an epoxy resin hardener, and a reactive group-containing (meth)acrylic copolymer. The adhesive composition constituting the adhesive layer 5 may further include a coupling agent, a curing accelerator, a filler, and the like.

Examples of the epoxy resin include bifunctional epoxy resins such as bisphenol A type epoxy resin, bisphenol F type epoxy resin, bisphenol S type epoxy resin, alicyclic epoxy resin, aliphatic chain epoxy resin, phenol novolac type epoxy resin, cresol novolac type epoxy resin, bisphenol A novolac type epoxy resin, diglycidyl etherified products of biphenol, diglycidyl etherified products of naphthalenediol, diglycidyl etherified products of phenols, diglycidyl etherified products of alcohols, and their alkyl substituted products, halides, and hydrogenated products, and novolac type epoxy resins. In addition, other generally known epoxy resins such as polyfunctional epoxy resins and heterocyclic-containing epoxy resins may be applied. Note that components other than the epoxy resin may be included as impurities to the extent that the properties are not impaired.

Examples of the epoxy resin hardener include phenolic resins that can be obtained by reacting a phenol compound and a xylylene compound, which is a divalent linking group, in the absence of a catalyst or in the presence of an acid catalyst. Examples of the phenol compound used for producing the phenolic resin include phenol, o-cresol, m-cresol, p-cresol, o-ethylphenol, p-ethylphenol, o-n-propylphenol, m-n-propylphenol, p-n-propylphenol, o-isopropylphenol, m-isopropylphenol, p-isopropylphenol, o-n-butylphenol, m-n-butylphenol, p-n-butylphenol, o-isobutylphenol, m-isobutylphenol, p-isobutylphenol, octylphenol, nonylphenol, 2,4-xylenol, 2,6-xylenol, 3,5-xylenol, 2,4,6-trimethylphenol, resorcinol, catechol, hydroquinone, 4-methoxyphenol, o-phenylphenol, m-phenylphenol, p-phenylphenol, p-cyclohexylphenol, o-allylphenol, p-allylphenol, O-benzylphenol, p-benzylphenol, o-chlorophenol, p-chlorophenol, o-bromophenol, p-bromophenol, o-iodophenol, p-iodophenol, O-fluorophenol, m-fluorophenol, and p-fluorophenol. As the xylylene compound, which is a divalent linking group used for producing the phenolic resin, the following xylylene dihalides, xylylene diglycols, and their derivatives can be used. That is, specific examples of the xylylene compound include α,α′-dichloro-p-xylene, α,α′-dichloro-m-xylene, α,α′-dichloro-o-xylene, α,α′-dibromo-p-xylene, α,α′-dibromo-m-xylene, α,α′-dibromo-o-xylene, α,α′-diiodo-p-xylene, α,α′-diiodo-m-xylene, α,α′-diiodo-o-xylene, α,α′-dihydroxy-p-xylene, α,α′-dihydroxy-m-xylene, α,α′-dihydroxy-o-xylene, α,α′-dimethoxy-p-xylene, α,α′-dimethoxy-m-xylene, α,α′-dimethoxy-o-xylene, α,α′-diethoxy-p-xylene, α,α′-diethoxy-m-xylene, α,α′-diethoxy-o-xylene, α,α′-di-n-propoxy-p-xylene, α,α′-di-n-propoxy-m-xylene, α,α′-di-n-propoxy-o-xylene, α,α′-diisopropoxy-p-xylene, α,α′-diisopropoxy-m-xylene, α,α′-diisopropoxy-o-xylene, α,α′-di-n-butoxy-p-xylene, α,α′-di-n-butoxy-m-xylene, α,α′-di-n-butoxy-o-xylene, α,α′-diisobutoxy-p-xylene, α,α′-diisobutoxy-m-xylene, α,α′-diisobutoxy-o-xylene, α,α′-di-tert-butoxy-p-xylene, α,α′-di-tert-butoxy-m-xylene, and α,α′-di-tert-butoxy-o-xylene.

When reacting the phenol compound and the xylylene compound, a phenolic resin can be obtained by using an acidic catalyst such as mineral acids like hydrochloric acid, sulfuric acid, phosphoric acid, and polyphosphoric acid; organic carboxylic acids like dimethyl sulfate, diethyl sulfate, p-toluenesulfonic acid, methanesulfonic acid, and ethanesulfonic acid; superacids like trifluoromethanesulfonic acid; strongly acidic ion exchange resins like alkanesulfonic acid type ion exchange resins; superacidic ion exchange resins like perfluoroalkanesulfonic acid type ion exchange resins (trade name: Nafion, manufactured by Du Pont, “Nafion” is a registered trademark); natural and synthetic zeolites; and activated clay (acid clay), and reacting at 50 to 250° C. until the raw material xylylene compound substantially disappears and the reaction composition becomes constant. The reaction time can be appropriately set depending on the raw materials and the reaction temperature, and can be, for example, about 1 to 15 hours, and can be determined while tracking the reaction composition by GPC (gel permeation chromatography) or the like.

The reactive group-containing (meth)acrylic copolymer may be, for example, an epoxy group-containing (meth)acrylic copolymer. The epoxy group-containing (meth)acrylic copolymer may be a copolymer obtained by using glycidyl (meth)acrylate as a raw material in an amount of 0.5 to 6% by mass with respect to the resulting copolymer. When the content of glycidyl (meth)acrylate is 0.5% by mass or more, high adhesive strength tends to be easily obtained, while when it is 6% by mass or less, gelation tends to be suppressed. The monomer constituting the remainder of the reactive group-containing (meth)acrylic copolymer may be, for example, an alkyl (meth)acrylate having an alkyl group with 1 to 8 carbon atoms such as methyl (meth)acrylate, styrene, acrylonitrile, or the like. Among these, the monomer constituting the remainder of the reactive group-containing (meth)acrylic copolymer may be ethyl (meth)acrylate and/or butyl (meth)acrylate. The mixing ratio can be adjusted in consideration of the Tg of the reactive group-containing (meth)acrylic copolymer. When the Tg is −10° C. or higher, there is a tendency to suppress the tackiness of the adhesive layer 5 in the B-stage state from becoming too high, and there is a tendency for excellent handleability. The glass transition temperature (Tg) of the epoxy group-containing (meth)acrylic copolymer may be, for example, 30° C. or lower. The polymerization method is not particularly limited, but examples include pearl polymerization, solution polymerization, and the like. An example of a commercially available epoxy group-containing (meth)acrylic copolymer is HTR-860P-3 (trade name, manufactured by Nagase ChemteX Corporation).

The weight average molecular weight of the epoxy group-containing (meth)acrylic copolymer may be 100,000 or more, and may be from 300,000 to 3,000,000 or from 500,000 to 2,000,000, from the viewpoints of adhesiveness and heat resistance. When the weight average molecular weight is 3,000,000 or less, a decrease in the filling property between the chip and the substrate supporting it can be suppressed. The weight average molecular weight is a polystyrene-equivalent value using a calibration curve prepared with standard polystyrene by gel permeation chromatography (GPC).

The coupling agent may be a silane coupling agent. Specific examples of the silane coupling agent include γ-ureidopropyltriethoxysilane, γ-mercaptopropyltrimethoxysilane, 3-phenylaminopropyltrimethoxysilane, 3-(2-aminoethyl)aminopropyltrimethoxysilane, and the like.

Examples of the curing accelerator include tertiary amines, imidazoles, quaternary ammonium salts, and the like. Specific examples of the curing accelerator include 2-methylimidazole, 2-ethyl-4-methylimidazole, 1-cyanoethyl-2-phenylimidazole, and 1-cyanoethyl-2-phenylimidazolium trimellitate.

The filler may be an inorganic filler. Specific examples of the inorganic filler include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, crystalline silica, and amorphous silica.

The thickness d1 of the adhesive layer 5 is from 30 to 50 μm, and may be, for example, 32 μm or more, 35 μm or more, or 37 μm or more, and may be 48 μm or less, 45 μm or less, or 43 μm or less. When the thickness of the adhesive layer 5 is from 30 to 50 μm, the effects shown in the present disclosure tend to be sufficiently obtained.

Note that the adhesive layer 5 may be an embodiment that does not include an epoxy resin and an epoxy resin hardener. For example, when the adhesive layer 5 includes a reactive group-containing (meth)acrylic copolymer, the adhesive layer 5 may be one that includes the reactive group-containing (meth)acrylic copolymer, a curing accelerator, and a filler.

For the adhesive layer 5, a varnish of the adhesive composition (varnish for forming the adhesive layer) may be prepared and coated on the surface of the pressure-sensitive adhesive layer 3, or the adhesive layer 5 may be formed on a release-treated film and then attached to the pressure-sensitive adhesive layer 3. The varnish of the adhesive composition (varnish for forming the adhesive layer) may be an organic solvent that can dissolve each component other than the filler and volatilizes upon heating. Specific examples of the organic solvent can be exemplified by the same ones as the organic solvent in the varnish of the ultraviolet-curable pressure-sensitive adhesive.

### (Integrated Film)

The integrated film 9 can be manufactured by a method including, for example, providing a dicing film 7 having a base layer 1 and a pressure-sensitive adhesive layer 3 provided on the base layer 1, and providing an adhesive layer 5 on the pressure-sensitive adhesive layer 3 of the dicing film 7.

### (Semiconductor Chip)

The semiconductor chip SC is obtained by singulating a semiconductor wafer, and can be obtained, for example, by a DBG process. The shape of the semiconductor chip SC in a plan view may be, for example, a square or a rectangle. The area of the semiconductor chip SC may be from 10 to 250 mm², and may be from 20 to 200 mm² or from 30 to 150 mm². The length of one side of the semiconductor chip SC is, for example, 1 mm or more, and may be from 2 to 18 mm or from 3 to 15 mm.

The thickness of the semiconductor chip SC (thickness Dsc described later) may be, for example, from 10 to 200 μm, and may be from 20 to 100 μm. Note that the thicknesses of the plurality of semiconductor chips SC may be the same or different from each other.

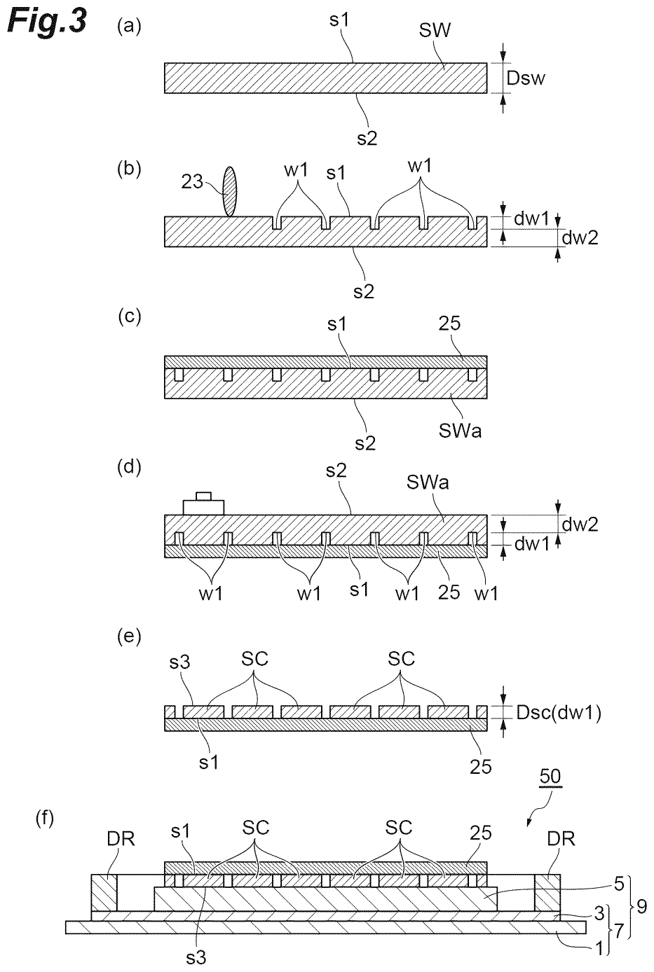

FIG. 3 is a schematic cross-sectional view for explaining one embodiment of a method for manufacturing a laminate. The laminate 10 may be a laminate produced by a method including: forming a groove along a dicing line on a circuit-forming surface of a semiconductor wafer (step (a)); grinding a back surface, which is opposite to the circuit-forming surface, of the semiconductor wafer in which the groove has been formed to at least a depth reaching the groove to produce a plurality of semiconductor chips (step (b)); and attaching the adhesive layer of the integrated film to back surfaces of the plurality of semiconductor chips (step (c)).

In step (a), a groove w1 is formed along a dicing line on a circuit-forming surface s1 of a semiconductor wafer SW (see FIGS. 3(a) and 3(b)).

Examples of the semiconductor wafer SW include compound semiconductors such as single-crystal silicon, polycrystalline silicon, various ceramics, and gallium arsenide. The semiconductor wafer SW usually has a circuit-forming surface s1 and a back surface s2 opposite to the circuit-forming surface s1.

The thickness Dsw of the semiconductor wafer SW is usually greater than the thickness Dsc of the semiconductor chip SC. The thickness Dsw of the semiconductor wafer SW may be, for example, from 50 to 3000 μm, from 100 to 2000 μm, or from 200 to 1500 μm.

The groove w1 is formed by performing half-cut dicing using a dicing blade 23 along the dicing lines of the semiconductor wafer SW (see FIG. 3(b)). Half-cut dicing means cutting to a depth dw1 (the depth dw1 may be less than the thickness Dsw of the semiconductor wafer SW) so as not to completely cut the semiconductor wafer SW. The half-cut dicing by the dicing blade 23 can be performed using a commercially available dicing saw. The groove w1 is formed on the circuit-forming surface s1 of the semiconductor wafer SW, for example, so as to form a grid pattern in a plan view.

In step (b), a back surface s2, which is opposite to the circuit-forming surface s1, of the semiconductor wafer SW in which the groove w1 has been formed (semiconductor wafer with a groove formed SWa) is ground by a portion corresponding to a thickness dw2 of the semiconductor wafer with a groove formed SWa to at least a depth dw1 reaching the groove w1, to produce a plurality of semiconductor chips SC (see FIGS. 3(c), 3(d), and 3(e)). In the semiconductor wafer with a groove formed SWa, the sum of the depth dw1 of the groove w1 and the thickness dw2 of the semiconductor wafer with a groove formed SWa may be equal to or less than the thickness Dsw of the semiconductor wafer SW.

In step (b), first, a back grinding tape 25 is attached on the circuit-forming surface s1 of the semiconductor wafer SW in which the groove w1 has been formed (see FIG. 3(c)). As the back grinding tape 25, a back grinding tape used in the field can be used, and it may be, for example, a back grinding tape including a pressure-sensitive adhesive layer including an ultraviolet-curable pressure-sensitive adhesive.

Subsequently, the back surface s2 of the semiconductor wafer SW in which the groove w1 has been formed is ground (see FIG. 3(d)). The back surface grinding of the semiconductor wafer SW in which the groove w1 has been formed can be performed using a general grinder. By grinding the back surface s2 in this manner, a plurality of semiconductor chips SC with a thickness Dsc can be produced, as shown in FIG. 3(e). The thickness Dsc may be equal to or less than the depth dw1. The semiconductor chip SC usually has a circuit-forming surface s1 and a back surface s3 opposite to the circuit-forming surface s1.

In step (c), the adhesive layer 5 of the above-mentioned integrated film 9 is attached to the back surfaces s3 of the plurality of semiconductor chips SC obtained above (see FIG. 3(f)). In this way, a laminate 50 can be obtained, which has, in this order, the base layer 1, the pressure-sensitive adhesive layer 3, the adhesive layer 5, the plurality of semiconductor chips SC, and the back grinding tape 25.

Subsequently, by peeling the back grinding tape 25 from the laminate 50, the laminate 10 can be obtained. When the back grinding tape 25 includes a pressure-sensitive adhesive layer including an ultraviolet-curable pressure-sensitive adhesive, by irradiating the pressure-sensitive adhesive layer of the back grinding tape 25 with ultraviolet light to cure the pressure-sensitive adhesive layer and reduce its adhesive strength, the back grinding tape 25 can be efficiently peeled from the laminate 50.

### <Step (B)>

In this step, the adhesive layer 5 is irradiated with a laser 15 through the gaps between the plurality of semiconductor chips SC to form a groove w in the adhesive layer 5 (see FIGS. 1(a) and 1(b)).

The plurality of semiconductor chips SC, which are obtained by singulating a semiconductor wafer and are disposed on the adhesive layer 5 of the integrated film 9, usually have gaps between the plurality of semiconductor chips SC. By irradiating the adhesive layer 5 with the laser 15 through the gaps, a groove w can be formed along the shape of the semiconductor chips SC in a plan view. Note that when irradiating the adhesive layer 5 with the laser 15, it is adjusted so that the adhesive layer 5 is not completely separated.

The irradiation with the laser 15 is performed, for example, from the semiconductor chip SC side through the gaps between the plurality of semiconductor chips SC, as shown in FIG. 1(b). The irradiation with the laser 15 can be performed using a commercially available laser saw. The frequency of the laser 15 may be, for example, from 30 to 250 kHz, from 50 to 200 kHz, or from 80 to 120 kHz. The output of the laser 15 may be, for example, from 0.05 to 2.0 W, from 0.1 to 1.0 W, or from 0.2 to 0.5 W. The feed speed in the irradiation with the laser 15 may be, for example, from 20 to 500 mm/s, from 50 to 400 mm/s, or from 100 to 300 mm/s.

The depth d2 of the groove w is 45% or less of the thickness d1 of the adhesive layer 5. When the depth d2 of the groove w is 45% or less of the thickness d1 of the adhesive layer 5, the occurrence of resin component climb-up of the adhesive layer on the side surfaces of the semiconductor chip can be suppressed, and as a result, it becomes possible to suppress the adhesion of debris derived from the adhesive layer on the semiconductor chip. The depth d2 of the groove w, in one embodiment, may be 42% or less, or 40% or less of the thickness d1 of the adhesive layer 5, and may be 10% or more, 15% or more, 20% or more, 25% or more, 28% or more, or 30% or more. The depth d2 of the groove w, in one embodiment, may be 40% or less, 35% or less, 30% or less, or 25% or less of the thickness d1 of the adhesive layer 5, and may be 10% or more, 15% or more, or 20% or more.

The ratio of the depth d2 of the groove w can be adjusted, for example, by appropriately adjusting the frequency, output, feed speed in irradiation, and the like of the laser 15.

### <Step (C)>

In this step, by expanding the base layer 1, the adhesive layer 5 in which the groove w has been formed is singulated to produce semiconductor chips with adhesive layer pieces attached 13 (see FIGS. 1(c) and 1(d)).

As a method for expanding the base layer 1, for example, a method of pushing up a region inside the dicing ring DR of the (base layer 1) of the dicing film 7 with a ring Ra under cooling conditions (cold expansion, see FIG. 1(c)) can be mentioned. The temperature of the cooling conditions may be, for example, from −15 to 0° C. By expanding the base layer 1, the adhesive layer 5 is separated along the groove w. By this separation, semiconductor chips with adhesive layer pieces attached 13, each having a semiconductor chip SC and an adhesive layer piece 5a which is a singulated piece of the adhesive layer 5, are formed on the pressure-sensitive adhesive layer 3.

After the ring Ra is lowered, in the dicing film 7, a region between the dicing ring DR and the semiconductor chips with adhesive layer pieces attached 13 may be heated by a heater H (see FIG. 1(d)). Due to the thermal shrinkage of the heated portion of the dicing film 7, it becomes possible to further widen the kerf width between the semiconductor chips with adhesive layer pieces attached 13.

The method for manufacturing a semiconductor device of the present embodiment may further include irradiating the pressure-sensitive adhesive layer 3 with ultraviolet light to form a cured pressure-sensitive adhesive layer 11 including a cured product of the ultraviolet-curable pressure-sensitive adhesive (step (D)), picking up the semiconductor chips with adhesive layer pieces attached 13 (step (E)), thermocompression bonding and adhering the picked-up semiconductor chips with adhesive layer pieces attached 13 and a support member 21 via the adhesive layer pieces 5a (step (F)), thermally curing the adhesive layer pieces 5a (step (G)), and the like.

### <Step (D)>

This step is a step performed when the pressure-sensitive adhesive layer 3 includes an ultraviolet-curable pressure-sensitive adhesive. When the pressure-sensitive adhesive layer 3 does not include an ultraviolet-curable pressure-sensitive adhesive, this step may be omitted. In this step, the pressure-sensitive adhesive layer 3 of the laminate 10 is irradiated with ultraviolet light to form a cured pressure-sensitive adhesive layer 11 including a cured product of the ultraviolet-curable pressure-sensitive adhesive (see FIGS. 2(a) and 2(b)).

The irradiation with ultraviolet light is performed, for example, from the base layer 1 side through the base layer 1, as shown in FIG. 2(a). The source of ultraviolet light irradiation is not particularly limited, but for example, a metal halide lamp, a high-pressure sodium lamp, a UV-LED lamp, or the like can be used. The illuminance of the ultraviolet light on the pressure-sensitive adhesive layer 3 may be, for example, from 1 to 1000 m W/cm², from 10 to 900 m W/cm², or from 30 to 800 m W/cm². The irradiation dose of the ultraviolet light on the pressure-sensitive adhesive layer 3 may be, for example, from 10 to 3000 mJ/cm², from 50 to 2500 mJ/cm², or from 100 to 2000 mJ/cm².

### <Step (E)>

In this step, if necessary, while separating the singulated semiconductor chips with adhesive layer pieces attached 13 from each other, they are pushed up from the base layer 1 side with a needle 17, and the pushed-up semiconductor chips with adhesive layer pieces attached 13 are picked up from the cured pressure-sensitive adhesive layer 11 (or the pressure-sensitive adhesive layer 3) by suction with a suction collet 19 (see FIG. 2(c)).

### <Step (F)>

In this step, the picked-up semiconductor chip with an adhesive layer piece attached 13 and a support member 21 are adhered by thermocompression bonding via the adhesive layer piece 5a. One or a plurality of semiconductor chips with adhesive layer pieces attached 13 (semiconductor chips SC) may be adhered to the support member 21.

The thermocompression bonding conditions for the semiconductor chip with an adhesive layer piece attached 13 can be appropriately adjusted depending on the constituent components of the adhesive layer piece 5a. The heating temperature in the thermocompression bonding may be, for example, from 80 to 160° C. The load in the thermocompression bonding may be, for example, from 5 to 15 N. The heating time in the thermocompression bonding may be, for example, from 0.5 to 20 seconds.

### <Step (G)>

In this step, the adhesive layer piece 5a is thermally cured. The thermal curing conditions for the adhesive layer piece 5a can be appropriately adjusted depending on the constituent components of the adhesive layer piece 5a. The heating temperature in the thermal curing may be, for example, from 60 to 200° C., from 90 to 190° C., or from 120 to 180° C. The heating time in the thermal curing may be from 30 minutes to 5 hours, from 1 to 3 hours, or from 2 to 3 hours. Note that the temperature or pressure may be changed stepwise.

In this way, a semiconductor device 40 (see FIG. 2(d)) can be manufactured, which includes (a plurality of) semiconductor chips SC, a support member 21 on which the semiconductor chips SC are mounted, and a cured product of the adhesive layer piece 5a (cured product of adhesive layer piece 5ac) that adheres the semiconductor chips SC and the support member 21.

According to the method for manufacturing a semiconductor device of the present embodiment, the occurrence of resin component climb-up of the adhesive layer on the side surfaces of the semiconductor chip can be suppressed, and as a result, it becomes possible to suppress the adhesion of debris derived from the adhesive layer on the semiconductor chip. Some embodiments of the method for manufacturing a semiconductor device are also excellent in that a sufficient kerf width between the semiconductor chips can be obtained after expansion.

### EXAMPLES

Hereinafter, the present disclosure will be described more specifically based on examples, but the present disclosure is not limited to these examples. Note that unless otherwise specified, all chemicals used were reagents (commercially available products).

### [Synthesis of (Meth)Acrylic Resin]

### (Production Example 1: Synthesis of (Meth)Acrylic Resin 1a)

The following components were placed in a 2000 mL flask equipped with a Three-One Motor, a stirring blade, and a nitrogen inlet tube.
Ethyl acetate (solvent): 635 parts by mass
2-Ethylhexyl acrylate: 395 parts by mass
2-Hydroxyethyl acrylate: 100 parts by mass
Methacrylic acid: 5 parts by mass
Azobisisobutyronitrile: 0.08 parts by mass

After stirring the contents until sufficiently uniform, bubbling was performed at a flow rate of 500 mL/min for 60 minutes to degas the dissolved oxygen in the system. The temperature was raised to 78° C. over 1 hour, and polymerization was carried out for 6 hours after the temperature was raised. Next, the reaction solution was transferred to a 2000 mL autoclave equipped with a Three-One Motor, a stirring blade, and a nitrogen inlet tube, heated at 120° C. and 0.28 MPa for 4.5 hours, and then cooled to room temperature (25±3° C., the same applies hereinafter).

Next, 490 parts by mass of ethyl acetate was added and stirred to dilute the contents. To this, 0.10 parts by mass of dioctyltin dilaurate was added as a urethanization catalyst, followed by the addition of 105.3 parts by mass of 2-methacryloyloxyethyl isocyanate (Karenz MOI (trade name), manufactured by Showa Denko K.K.), and the mixture was reacted at 70° C. for 6 hours, then cooled to room temperature. Subsequently, ethyl acetate was further added to adjust the non-volatile content in the (meth)acrylic resin solution to 35% by mass, thereby obtaining a solution containing the (meth)acrylic resin 1a of Production Example 1.

### (Production Example 2: Preparation of Dicing Film 2a)

A varnish of an ultraviolet-curable pressure-sensitive adhesive (varnish for forming a pressure-sensitive adhesive layer) was prepared by mixing the following components. The amount of ethyl acetate (solvent) was adjusted so that the total solid content of the varnish was 25% by mass.
(Meth)acrylic resin (A): Solution containing (meth)acrylic resin 1a of Production Example 1:100 parts by mass (solid content)
Photoinitiator: Omnirad 184 (trade name (“Omnirad” is a registered trademark), 1-hydroxycyclohexyl phenyl ketone, manufactured by IGM RESINS B.V.): 1.0 part by mass
Photoinitiator: Omnirad 819 (trade name (“Omnirad” is a registered trademark), phenylbis(2,4,6-trimethylbenzoyl)phosphine oxide, manufactured by IGM RESINS B.V.): 0.2 parts by mass
Crosslinking agent: Coronate L (trade name, polyfunctional isocyanate (reaction product of tolylene diisocyanate and trimethylolpropane), manufactured by Nippon Polyurethane Industry Co., Ltd., solid content 75% by mass): 2.0 parts by mass (solid content)·
Ethyl acetate (solvent)

A polyethylene terephthalate film (width 450 mm, length 500 mm, thickness 38 μm) with one side subjected to a release treatment was provided. The varnish of the ultraviolet-curable pressure-sensitive adhesive was applied to the release-treated surface using an applicator, and then dried at 80° C. for 3 minutes. This yielded a dicing film 2a including the polyethylene terephthalate film as a base layer and a pressure-sensitive adhesive layer with a thickness of 10 μm formed thereon.

A polyolefin film (width 450 mm, length 500 mm, thickness 90 μm) with one side subjected to a corona treatment was provided. The corona-treated surface and the pressure-sensitive adhesive layer of the above laminate were attached to each other at room temperature. Subsequently, the pressure-sensitive adhesive layer was transferred to the polyolefin film (cover film) by pressing with a rubber roll. Thereafter, the film was left at room temperature for 3 days to obtain the dicing film 2a with a cover film of Production Example 2.

### Production Example 3: Preparation of Die Bonding Film 3a

A varnish for forming an adhesive layer was prepared by mixing the following components. First, cyclohexanone (solvent) was added to a mixture containing the following components and mixed by stirring, and then further kneaded for 90 minutes using a bead mill.
Epoxy resin: N-500P-10 (trade name, manufactured by DIC Corporation, o-cresol novolac type epoxy resin, epoxy equivalent: 204 g/eq, softening point: 75-85° C.): 11 parts by mass
Epoxy resin: EXA-830CRP (trade name, manufactured by DIC Corporation, bisphenol F type epoxy resin, epoxy equivalent: 160, molecular weight: 1800, softening point: 85° C.): 8 parts by mass
Epoxy resin hardener: MEH-7800M (trade name, manufactured by Meiwa Plastic Industries, Ltd. (now UBE Corporation), phenyl aralkyl type phenolic resin, hydroxyl equivalent: 174 g/eq, softening point: 80° C.): 15 parts by mass
Coupling agent: NUC A-189 (trade name, manufactured by Momentive Performance Materials Japan LLC, silane coupling agent, γ-mercaptopropyltrimethoxysilane): 0.1 parts by mass
Coupling agent: NUC A-1160 (trade name, manufactured by Momentive Performance Materials Japan LLC, silane coupling agent, γ-ureidopropyltriethoxysilane): 0.2 parts by mass
Filler: SC2050-HLG (trade name, manufactured by Admatechs Co., Ltd., silica filler, average particle size: 0.50 μm): 40 parts by mass

The following components were further added to the mixture obtained as described above, and then a varnish for forming an adhesive layer was obtained through steps of stirring, mixing, and vacuum degassing.
Reactive group-containing (meth)acrylic copolymer: SG-P3 (trade name, manufactured by Nagase ChemteX Corporation, acrylic rubber, weight average molecular weight: 800,000, Tg: 12° C.): 24.6 parts by mass
Curing accelerator: Curezol 2PZ-CN (trade name (“Curezol” is a registered trademark), manufactured by Shikoku Chemicals Corporation, 1-cyanoethyl-2-phenylimidazole): 0.1 parts by mass

A polyethylene terephthalate film (thickness 35 μm) with one side subjected to a release treatment was provided. The varnish for forming an adhesive layer was applied to the release-treated surface using an applicator, and then heated and dried at 140° C. for 5 minutes. This yielded a die bonding film 3a including the polyethylene terephthalate film (carrier film) and an adhesive layer (B-stage state) with a thickness of 40 μm formed thereon.

### Production Example 4: Preparation of Integrated Film 4a

The die bonding film 3a, together with the carrier film, was cut into a circular shape with a diameter of 312 mm. The dicing film 2a, from which the polyethylene terephthalate film had been peeled, was attached to the cut die bonding film 3a at room temperature and then left at room temperature for one day. Thereafter, the dicing film 2a was cut into a circular shape with a diameter of 370 mm. In this way, the integrated film 4a of Production Example 4 was obtained.

### [Preparation of Laminate]

A semiconductor wafer (silicon wafer) with a thickness of 775 μm was provided and a half-cut was performed on the circuit-forming surface (front surface) of the semiconductor wafer using a full-auto dicer (DFD6361, manufactured by DISCO Corporation) to form a groove with a depth of 60 μm. The dicing blade used was ZH05-SD4000-N1-70-DD manufactured by DISCO Corporation, and the rotation speed and cutting speed were 40,000 rpm and 30 mm/s, respectively. The size of the semiconductor chip was set to 4 mm×12 mm.

Next, a back grinding tape was attached to the circuit-forming surface (front surface) of the semiconductor wafer using a back grinding tape laminator (RAD-3520F/12, manufactured by Lintec Corporation), and then the semiconductor wafer was ground from the back surface side using a grinder (DGP8761, manufactured by DISCO Corporation) so that the finally obtained semiconductor chip thickness would be 90 μm, thereby singulating the semiconductor wafer into a plurality of semiconductor chips.

Subsequently, in order to reduce the adhesive force between the back grinding tape and the semiconductor chips, the back grinding tape was irradiated with ultraviolet light using a wafer mounter (DFM2800, manufactured by DISCO Corporation). Thereafter, using the same wafer mounter (DFM2800, manufactured by DISCO Corporation), the integrated film 4a was attached to the back surface of the singulated semiconductor wafer (back surface of the semiconductor chips) under the conditions of a temperature of 70° C., a tension level of 5, and a lamination speed of 10 mm/sec. At this time, a ring frame was attached to the outer peripheral region of the dicing tape. Thereafter, by peeling off the back grinding tape, a plurality of laminates were produced, each including an integrated film having, in this order, a base layer, a pressure-sensitive adhesive layer, and an adhesive layer, and a plurality of semiconductor chips obtained by singulating a semiconductor wafer, the plurality of semiconductor chips being disposed on the adhesive layer of the integrated film.

### Example 1

### [Preparation and Evaluation of Evaluation Laminate]

### (Preparation of Evaluation Laminate)

In the prepared laminate, a laser was irradiated through the gaps between the semiconductor chips using a laser saw (DFL7160, manufactured by DISCO Corporation) to form a groove in the adhesive layer. The laser irradiation conditions were a frequency of 100 kHz, an output of 0.7 W, a feed speed of 200 mm/s, a defocus amount of −0.09 mm, and a laser width of 3.7 μm. The laser width was determined in advance by actual measurement according to the following procedure. First, the integrated film 4a was provided as a sample, and the adhesive layer was irradiated with a laser under the above laser irradiation conditions. Next, the groove provided on the surface of the adhesive layer was observed, and the width of the groove was measured to determine the laser width.

Next, the base layer was stretched by cold expansion under the following conditions using a die separator (DDS2300, manufactured by DISCO Corporation), thereby separating the adhesive layer. Thereafter, the dicing film was shrunk by heating under the following conditions.

### (Cold Expansion Conditions)

Cooling temperature: −2° C.
Cooling time: 100 seconds
Push-up amount: 14 mm
Push-up speed: 8 mm/sec
Hold time after push-up: 3 seconds

### (Heating Conditions)

Heater temperature: 250° C.
Heater rotation speed: 5°/sec
Push-up amount: 9 mm
Push-up speed: 1 mm/sec
Tape cooling wait time: 0 seconds

Next, using the same die separator, in order to reduce the adhesive force between the pressure-sensitive adhesive layer and the adhesive layer, the pressure-sensitive adhesive layer was irradiated with ultraviolet light from the base layer side at an illuminance of 80 mW/cm² and an irradiation dose of 130 mJ/cm² to form a cured pressure-sensitive adhesive layer. In this way, a plurality of evaluation laminates of Example 1 were obtained, each having, in this order, a base layer, a cured pressure-sensitive adhesive layer, and a plurality of semiconductor chips with adhesive layer pieces attached.

### (Evaluation of Evaluation Laminate)

### (1) Measurement of Groove Depth by Laser Irradiation and Climb-up Height of Resin Component of Adhesive Layer

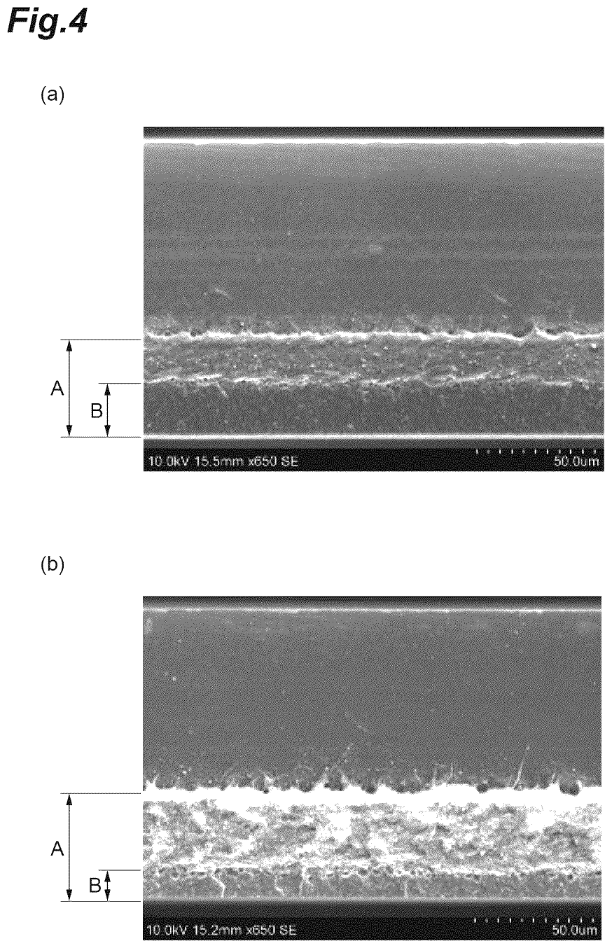

For the evaluation laminate of Example 1, the groove depth by laser irradiation and the climb-up height of the resin component of the adhesive layer were measured. A semiconductor chip with an adhesive layer piece attached was peeled from the evaluation laminate of Example 1 using tweezers, and the side surface of the semiconductor chip with an adhesive layer piece attached was observed using an SEM (scanning electron microscope, SU1510, manufactured by Hitachi High-Technologies Corporation) to measure the groove depth by laser irradiation and the climb-up height of the resin component of the adhesive layer. FIG. 4 is an SEM (scanning electron microscope) image of a side surface of a semiconductor chip taken after forming a groove in the adhesive layer and expanding it under cooling conditions, where FIG. 4(a) is an SEM image of Example 1, and FIG. 4(b) is an SEM image of Comparative Example 1. In FIG. 4, thickness A represents the thickness of the adhesive layer after laser irradiation and expansion under cooling conditions, and thickness B represents the thickness of the separated portion of the adhesive layer separated by expansion. The value obtained by subtracting thickness B from the thickness of the adhesive layer before laser irradiation (40 μm) corresponds to the depth of the groove formed in the adhesive layer by laser irradiation. The value obtained by subtracting the thickness of the adhesive layer before laser irradiation (40 μm) from thickness A corresponds to the climb-up height of the resin component of the adhesive layer. The results are shown in Table 1.

### (2) Measurement of Debris Scattering Distance

For the evaluation laminate of Example 1, debris on the surface of the semiconductor chip of the semiconductor chip with an adhesive layer piece attached was observed using a 3D measuring laser microscope (OLS4100, manufactured by Olympus Corporation). At a magnification of 20×, the debris scattering distance from the chip edge was measured from the obtained image using a measurement function. The observation was performed with N=8, and the average value was taken as the debris scattering distance from the chip edge. A larger debris scattering distance indicates a larger amount of debris generated from the adhesive layer and a larger amount of debris adhesion. The results are shown in Table 1.

### (3) Evaluation of Kerf Width

In the evaluation laminate of Example 1, the width of the gap (kerf width) between the grid-like semiconductor chips was measured by microscopic observation. The width of the gap along the MD direction (Machine Direction, the direction parallel to the longitudinal direction (flow direction) in the original roll of the base film) or the TD direction (Transverse Direction, the direction orthogonal to the MD direction (perpendicular direction)) around the semiconductor chip was measured at two locations in the vicinity of each of four positions that divide the portion corresponding to the outer periphery of the semiconductor wafer (silicon wafer) into four equal parts, and at one location in the central part of the semiconductor wafer. The average values of the widths of the gaps along the MD direction or the TD direction measured at a total of nine locations were respectively determined and taken as the kerf width in the MD direction or the TD direction. A large kerf width (e.g., 45 μm or more) tends to suppress the occurrence of problems when picking up the semiconductor chips with adhesive layer pieces attached. The results are shown in Table 1.

### (4) Evaluation of Separation Width

In the evaluation laminate of Example 1, the separation width of the adhesive layer in the gap between the grid-like semiconductor chips was measured by microscopic observation. The separation width of the adhesive layer was determined by measuring the width of the transmitted portion when light was applied from the base layer side in the evaluation laminate. More specifically, the width of the transmitted portion along the MD direction or the TD direction around the semiconductor chip was measured at two locations in the vicinity of each of four positions that divide the portion corresponding to the outer periphery of the semiconductor wafer (silicon wafer) into four equal parts, and at one location in the central part of the semiconductor wafer. The average values of the widths of the transmitted portions along the MD direction or the TD direction measured at a total of nine locations were respectively determined and taken as the separation width in the MD direction or the TD direction. A large separation width (e.g., 10 μm or more) tends to suppress the occurrence of problems when picking up the semiconductor chips with adhesive layer pieces attached. The results are shown in Table 1.

### Examples 2,3 and Comparative Example 1,2

### [Preparation and Evaluation of Evaluation Laminates]

Evaluation laminates of Examples 2, 3 and Comparative Examples 1, 2 were prepared in the same manner as in Example 1, except that the grooves were formed in the adhesive layer under the laser irradiation conditions shown in Table 1. Using the prepared evaluation laminates, evaluations were performed in the same manner as in Example 1. The results are shown in Table 1.

TABLE 1

| | | Comp. | Comp. | | | |
|---|---|---|---|---|---|---|
| | | Exam. 1 | Exam. 2 | Exam. 1 | Exam. 2 | Exam. 3 |
| Laser irradiation conditions | Output (W) | 1.0 | 1.0 | 0.7 | 0.5 | 0.4 |
| | Speed (mm/s) | 150 | 200 | 200 | 200 | 200 |
| | Laser width (μm) | 10.8 | 8.8 | 3.7 | 3.3 | 2.6 |
| Thickness of adhesive layer (μm) | | 40 | 40 | 40 | 40 | 40 |
| Depth of groove by laser irradiation in adhesive layer (μm) | | 25.3 | 22.9 | 16.2 | 11.9 | 8.9 |
| Ratio of groove depth to adhesive layer thickness (%) | | 62.5 | 57.5 | 40.0 | 30.0 | 22.5 |
| Climb-up height of resin component of adhesive layer (μm) | | 7.6 | 5.8 | 4.0 | 3.7 | 1.5 |
| Scattering distance of debris (μm) | | 52 | 55 | 46 | 29 | 23 |
| Kerf width (average) (μm) | MD direction | 54.4 | 57.0 | 55.6 | 52.2 | 49.3 |
| | TD direction | 57.5 | 59.5 | 63.7 | 52.6 | 56.4 |
| Separation width (average) (μm) | MD direction | 13.5 | 15.3 | 15.8 | 14.8 | 12.7 |
| | TD direction | 20.2 | 21.5 | 25.8 | 19.2 | 22.5 |

As shown in Table 1, in the case where the thickness of the adhesive layer is from 30 to 50 μm, it was found that the evaluation laminates of Examples 1 to 3, which were adjusted so that the groove depth was 45% or less of the thickness of the adhesive layer, had a smaller debris scattering distance on the surface of the semiconductor chip and a smaller amount of debris, compared to the evaluation laminates of Comparative Examples 1 and 2, which were adjusted so that the groove depth was more than 45% of the thickness of the adhesive layer. From these facts, it was confirmed that the method for manufacturing a semiconductor device of the present disclosure can suppress the adhesion of debris derived from the adhesive layer on semiconductor chips.

Reference Signs List

1 . . . base layer, 3 . . . pressure-sensitive adhesive layer, 5 . . . adhesive
layer, 5a . . . adhesive layer piece, 5ac . . . cured product of adhesive layer
piece, 7 . . . dicing film, 9 . . . integrated film, 10, 50 . . . laminate, 11 . . .
cured pressure-sensitive adhesive layer, 13 . . . semiconductor chip with
adhesive layer piece attached, 15 . . . laser, 17 . . . needle, 19 . . . suction
collet, 21 . . . support member, 23 . . . dicing blade, 25 . . . back grinding
tape, 40 . . . semiconductor device, SC . . . semiconductor chip, SW . . .
semiconductor wafer, SWa . . . semiconductor wafer with a groove
formed, DR . . . dicing ring, s1 . . . circuit-forming surface, s2, s3 . . .
back surface, w, w1 . . . groove.

1. A method for manufacturing a semiconductor device, the method comprising:
providing a laminate comprising a dicing/die-bonding integrated film having, in this order, a base layer, a pressure-sensitive adhesive layer, and an adhesive layer, and a plurality of semiconductor chips obtained by singulating a semiconductor wafer, the plurality of semiconductor chips being disposed on the adhesive layer of the dicing/die-bonding integrated film;
irradiating the adhesive layer with a laser through gaps between the plurality of semiconductor chips to form a groove in the adhesive layer; and
singulating the adhesive layer in which the groove has been formed by expanding the base layer to produce semiconductor chips with adhesive layer pieces attached,
wherein a thickness of the adhesive layer is from 30 to 50 μm, and
a depth of the groove is 45% or less of the thickness of the adhesive layer.

2. The method according to claim 1,
wherein the laminate is a laminate produced by a method including:
forming a groove along a dicing line on a circuit-forming surface of the semiconductor wafer;
grinding a back surface, which is opposite to the circuit-forming surface, of the semiconductor wafer in which the groove has been formed to at least a depth reaching the groove to produce the plurality of semiconductor chips; and
attaching the adhesive layer of the dicing/die-bonding integrated film to back surfaces of the plurality of semiconductor chips.

3. The method according to claim 1, wherein the depth of the groove is 40% or less of the thickness of the adhesive layer.

4. The method according to claim 1, wherein the depth of the groove is 10% or more of the thickness of the adhesive layer.

5. The method according to claim 1, wherein the depth of the groove is from 20% to 40% of the thickness of the adhesive layer.

6. The method according to claim 1, wherein expanding the base layer is performed under cooling conditions.

7. The method according to claim 6, wherein the expanding the base layer is performed at a temperature in a range of from −15 to 0° C.

8. The method according to claim 1, wherein the adhesive layer is formed from an adhesive composition comprising an epoxy resin, an epoxy resin hardener, and a reactive group-containing (meth)acrylic copolymer.

9. The method according to claim 1, wherein the pressure-sensitive adhesive layer comprises an ultraviolet-curable pressure-sensitive adhesive.
